(19) United States
(12) Patent Application Publication
(10) Pub. No.: US 2026/0178790 A1
(43) Pub. Date: Jun. 25, 2026

(54) ISOLATING OPERATION PLANNING DEVICE, ISOLATING OPERATION PLANNING METHOD, AND PROGRAM

(71) Applicant: HITACHI, LTD., Tokyo (JP)

(72) Inventors: Masashi YAMAMOTO, Tokyo (JP); Tetsushi ONO, Tokyo (JP)

(21) Appl. No.: 18/856,075

(22) PCT Filed: Feb. 17, 2023
(86) PCT No.: PCT/JP2023/005631

§ 371 Date: Oct. 11, 2024

(30) Foreign Application Priority Data
Apr. 11, 2022 (JP) 2022-065057

(51) Int. Cl. G06F 30/18

(52) U.S. Cl. CPC G06F 30/18

(57) ABSTRACT

An isolating operation planning device has an isolating operation planning unit that, in order to perform isolating operation for a power system section isolated from a power system, creates a proposed isolating operation plan (DP) with areas as isolating operation sections, the areas having at least distributed power sources therein or being equipped with power supply vehicles, among areas that are included in the isolating power system section and are divided by adjacent switches; a system analysis unit that performs system analysis based on the proposed isolating operation plan (DP) and determines whether isolating operation is able to be performed; and a constraint addition unit that, when the system analysis unit determines that isolating operation is not able to be performed, adds a constraint condition (CC) when creating the proposed isolating operation plan (DP) to cause the isolating operation planning unit to create the proposed isolating operation plan (DP) again.

### TECHNICAL FIELD

The present invention relates to an isolating operation planning device, an isolating operation planning method, and a program.

### BACKGROUND ART

In recent years, the introduction of distributed power sources such as renewable energy power sources into power systems has been progressing. On the other hand, large-scale disasters such as typhoons and floods tend to increase, and cases of large-scale power outages and long recovery times due to core system accidents and multiple accidents in power distribution systems have become apparent. Power infrastructure is required to respond to these power supply disruptions. In the future, new power system operations are required to realize widespread and early power outage recovery and subsequent stable power supply while making maximum use of distributed power sources connected to a power system.

In particular, in the power infrastructure, the introduction of distributed power sources including solar power generation has been significantly promoted in the power distribution system, and isolating operation in emergencies is being considered. Meanwhile, in isolating operation, it is expected that a problem will arise in that stable power supply cannot be achieved due to demand in an isolating operation system, the output of a distributed power source, and transient phenomena during isolating operation. For this reason, there is a need to stably continue isolating operation in the power distribution system in the event of an emergency and to maximize the number of consumers who recover from a power outage.

The background art of this technical field is disclosed in PTL 1. The abstract of this document states “A power conditioner 100 includes a first self-sustaining operation output terminal 107, a second self-sustaining operation output terminal 108, an inverter 102, a first current sensor 105 that detects a first current output by the inverter 102, a second current sensor 106 that detects a second current supplied to either the first self-sustaining operation output terminal 107 or the second self-sustaining operation output terminal 108, a control unit 111 that issues a warning or stops the operation of the inverter 102 when the first current is equal to or greater than a predetermined first threshold value or the second current is equal to or greater than a predetermined second threshold value, and a storage unit 109, and the control unit 111 controls the inverter 102 in accordance with a current flowing through the self-sustaining operation output terminal with a lower priority and a current of a load connected to the self-sustaining operation output terminal with a higher priority”.

### CITATION LIST

### Patent Literature

PTL 1: JP2020-48412A

### SUMMARY OF INVENTION

### Technical Problem

However, in the above-described technology, there is a demand for formulating even more appropriate isolating operation plans.

The invention has been conceived in view of the above-described circumstances, and an object thereof is to provide an isolating operation planning device, an isolating operation planning method, and a program which are capable of formulating an appropriate isolating operation plan.

### Solution to Problem

In order to solve the above problems, an isolating operation planning device of the present invention includes an isolating operation planning unit that, in order to perform isolating operation for a power system section isolated from a power system, creates a proposed isolating operation plan with areas as isolating operation sections, the areas having at least distributed power sources therein or being equipped with power supply vehicles, among areas that are included in the isolating power system section and are divided by adjacent switches, a system analysis unit that performs system analysis based on the proposed isolating operation plan and determines whether isolating operation is able to be performed, and a constraint addition unit that, when the system analysis unit determines that isolating operation is not able to be performed, adds a constraint condition when creating the proposed isolating operation plan to cause the isolating operation planning unit to create the proposed isolating operation plan again.

### Advantageous Effects of Invention

According to the invention, it is possible to formulate an appropriate isolating operation plan.

### BRIEF DESCRIPTION OF DRAWINGS

FIG. 1 is a block diagram of an isolating operation planning device according to a first embodiment.

FIG. 2 is a diagram showing a configuration example of a power distribution system.

FIG. 3 is a diagram showing an example of a data configuration of system information.

FIG. 4 is a diagram showing an example of a data configuration of facility damage information.

FIG. 5 is a diagram showing an example of a data configuration of power outage information.

FIG. 6 is a diagram showing an example of a data configuration of critical load information.

FIG. 7 is a diagram showing an example of a data configuration of map information.

FIG. 8 is a diagram showing an example of a data configuration of resource information.

FIG. 9 is a diagram showing an example of a data configuration of past demand data.

FIG. 10 is a diagram showing an example of a data configuration of past distributed power source output data.

FIG. 11 is a flowchart of a proposed isolating operation plan creation routine.

FIG. 12 is a diagram showing an example of an isolating operation data matrix C.

FIG. 13 is a flowchart of a system analysis routine.

FIG. 14 is a flowchart of a constraint addition routine.

FIG. 15 is a flowchart of a display processing routine.

FIG. 16 is a diagram showing a configuration example of a screen displayed on a display device by a screen output unit.

FIG. 17 is a block diagram of a computer.

### DESCRIPTION OF EMBODIMENTS

### [Premise of Embodiment]

The present applicant has proposed technology related to isolating operation in Japanese Patent Application No. 2021-075032.

According to this technology, it is possible to plan a final system configuration in isolating operation so that as many loads as possible can be recovered as rapidly as possible. However, the order of power restoration for each switch section (area) is not taken into consideration, making it difficult to evaluate system stability up to the final system configuration. Thereby, a re-power outage is caused in a process of reaching the final system configuration, which results in a possibility that a load capacity to be restored from a power outage cannot be maximized.

Consequently, an embodiment to be described below provides an isolating operation planning device and an isolating operation planning method which are capable of planning a system configuration for each time in isolating operation of a power distribution system and maximizing a load capacity to be restored from a power outage while confirming that power can be supplied without causing a power outage at each time.

More specifically, in the embodiment to be described below, “an isolating operation planning device for restoring a power system section isolated due to a power system accident from a power outage, in which a switch section (area) divided by adjacent switches” is defined for the isolating power system section. Further, in the embodiment to be described below, an isolating operation planning unit that creates a proposed isolating operation plan considering the time when power is supplied to each area is provided, in which at least an area which has a distributed power source therein or where a power supply vehicle is deployed is set as an isolating operation section. Furthermore, in the embodiment to be described below, a system analysis unit that evaluates system stability at each time section for a selected proposed isolating operation plan, and a constraint addition unit that estimates a stable plan based on a system analysis result received and adds a plan selection constraint to the isolating operation planning unit are provided.

Thereby, according to the embodiment to be described below, it is possible to formulate an appropriate isolating operation plan that includes the timing of power restoration in each area in order to restore a power outage area as rapidly and widely as possible while avoiding a re-power outage in a process leading up to a final system configuration in isolating operation of a power system.

### First Embodiment

### <Configuration of First Embodiment>

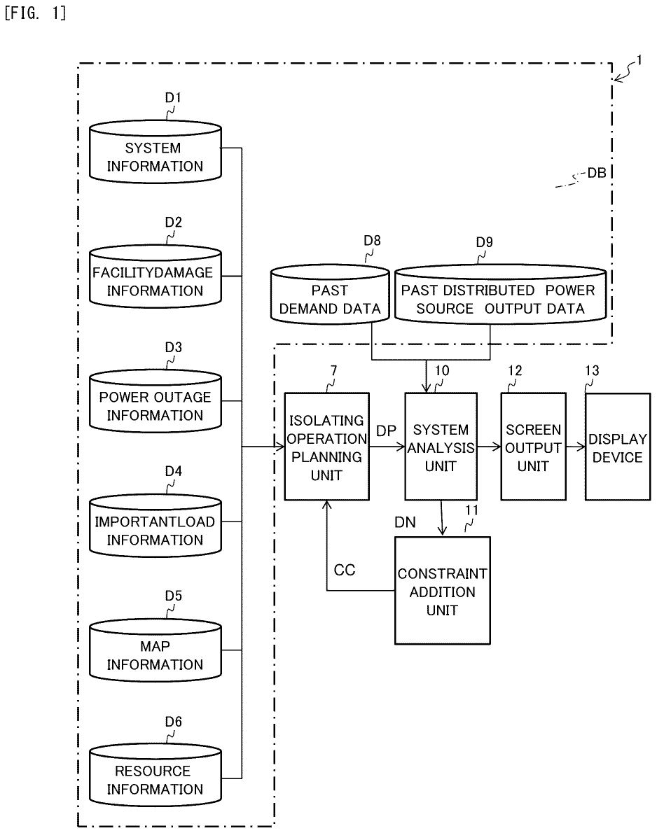

FIG. 1 is a block diagram of an isolating operation planning device 1 (computer) according to a first embodiment.

The isolating operation planning device 1 includes an isolating operation planning unit 7 (isolating operation planning means), a system analysis unit 10 (system analysis means), a constraint addition unit 11 (constraint addition means), a screen output unit 12 (screen output process), a display device 13, and a database unit DB. It is preferable that the display device 13 be a display including, for example, a liquid crystal panel or an organic electroluminescence (EL) panel.

The isolating operation planning unit 7 outputs a proposed isolating operation plan DP (details will be described below). The system analysis unit 10 determines whether the proposed isolating operation plan DP can be adopted. When the proposed isolating operation plan DP can be adopted, the system analysis unit 10 outputs the determination result to the display device 13 via the screen output unit 12. On the other hand, when the proposed isolating operation plan DP cannot be adopted, the system analysis unit 10 outputs unadoptable information DN indicating that the proposed isolating operation plan DP cannot be adopted to the constraint addition unit 11. In response to the unadoptable information DN, the constraint addition unit 11 outputs a constraint condition CC, which is a constraint at the time of creating the proposed isolating operation plan DP, to the isolating operation planning unit 7. Details of the isolating operation planning unit 7, the system analysis unit 10, and the constraint addition unit 11 will be described below.

The database unit DB stores system information D1, facility damage information D2, power outage information D3, critical load information D4, map information D5, resource information D6, past demand data D8, and past distributed power source output data D9.

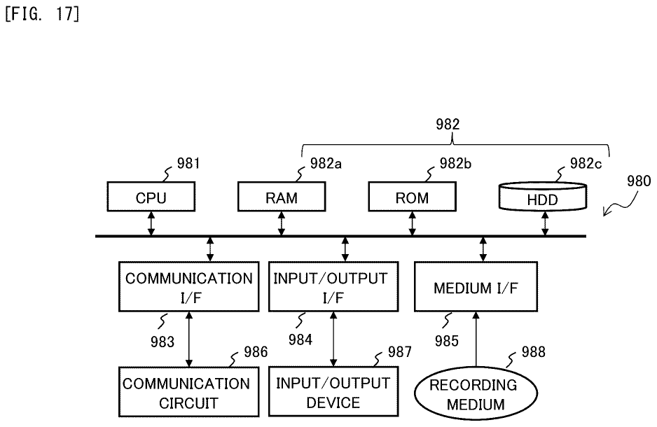

FIG. 17 is a block diagram of a computer 980. The isolating operation planning device 1 shown in FIG. 1 includes one or a plurality of computers 980 shown in FIG. 17. That is, the isolating operation planning device 1 may be constituted by one computer 980, or may be constituted by a plurality of computers 980 connected to each other.

In FIG. 17, the computer 980 includes a CPU 981, a storage unit 982, a communication interface (I/F) 983, an input/output I/F 984, and a medium I/F 985.

Here, the storage unit 982 includes a RAM 982a, a ROM 982b, and an HDD 982c. The communication I/F 983 is connected to a communication circuit 986. The input/output I/F 984 is connected to an input/output device 987. The medium I/F 985 reads and writes data from and to a recording medium 988. The ROM 982b stores control programs executed by the CPU, various data, and the like. The CPU 981 executes application programs read into the RAM 982a to realize various functions. The inside of the isolating operation planning device 1 shown in FIG. 1 shows the functions realized by the application programs and the like as blocks.

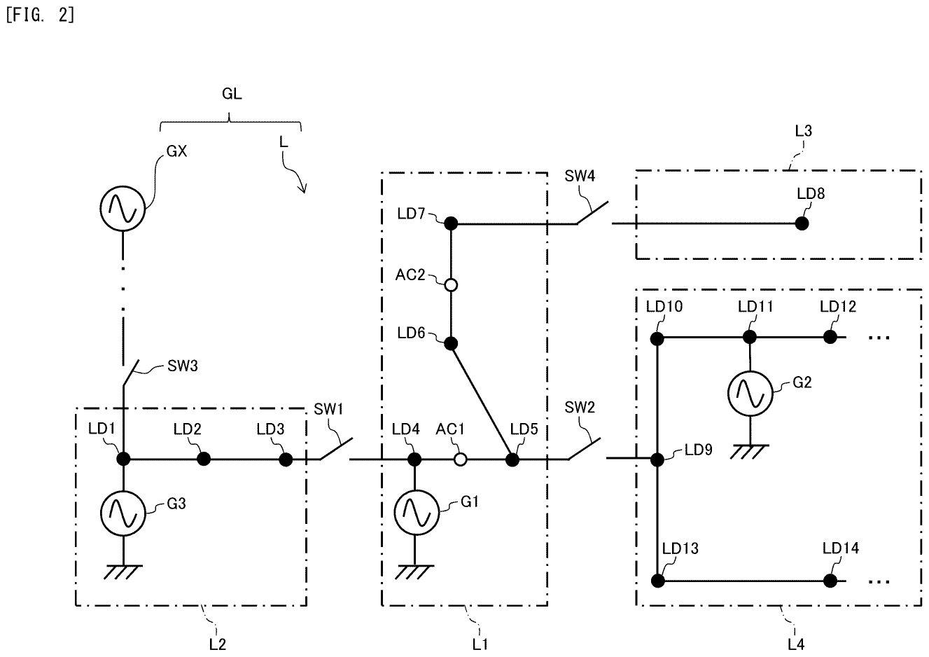

FIG. 2 is a diagram showing a configuration example of a power distribution system L (power system section) applicable to this embodiment.

The power distribution system L includes a plurality of consumers LD1 to LD14, a plurality of distributed power sources G1 to G3, and a plurality of switches SW1 to SW4. Here, the “switch” is a concept that also includes circuit breakers and the like. The power distribution system L is a part of a power system GL, and is connected to another part of the power system GL via the switch SW3. In the power system GL, an external power source GX is provided outside the power distribution system L.

In the example shown in the drawing, two damaged locations AC1 and AC2 are generated in the power distribution system L. Here, the “damaged location” is a location where power distribution is hindered due to an accident, a malfunction, or the like. As described above, the section divided by the switches SW1 to SW4 is referred to as an “area”. In the example shown in the drawing, the power distribution system L includes four areas L1 to L4.

In a state where the damaged locations AC1 and AC2 are not generated and, for example, normal operation is being executed, the switches SW1 to SW4 are closed. Thereby, the consumers LD1 to LD14 can receive power supplied from the external power source GX and the distributed power sources G1 to G3. However, when an accident occurs at the damaged locations AC1 and AC2, the switches SW1 to SW4 are opened and the power distribution system L is isolated from the external power source GX. Then, when the switches SW1 to SW4 are closed again after the accident is cleared, the power distribution system L can be recovered.

The isolating operation planning device 1 (see FIG. 1) of this embodiment plans how to operate the system during a recovery waiting period up to the recovery after an accident occurs. For example, when a large-scale power outage occurs due to an earthquake or the like, a recovery period is gradually extended, and a period up to the recovery may take several days to several tens of days, and this embodiment is particularly useful when a long-term power outage occurs.

In the state of this type of recovery waiting, the switches SW1 to SW4 are all open at the beginning. However, there is a possibility that a section that includes one or a plurality of areas in the power distribution system L and that includes consumers and distributed power sources will form an isolating operation section. For example, in FIG. 2, an area L2 divided by the switches SW1 and SW3 includes the consumers LD1 to LD3 and the distributed power source G3, which results in a possibility that an isolating operation section can be formed.

Similarly, an area L1, which is divided by the switches SW1, SW2, and SW4, includes the consumers LD4 to LD7 and the distributed power source G1, and thus there is a possibility that an isolating operation section can be formed. Similarly, an area L4, which is divided by the switch SW2, includes the consumers LD9 to LD14 and the distributed power source G2, and thus there is a possibility that an isolating operation section can be formed. However, an area L3, which is divided by the switch SW4, includes the consumer LD8 but does not include a distributed power source. Thus, the area L3 cannot form an isolating operation section when the switch SW4 is opened.

In the above description, an area divided by adjacent switches is set as an isolating operation section, but a plurality of adjacent areas among the areas L1 to L4 may be set as isolating operation sections. In addition, the distributed power sources G1 to G3 may be renewable energy power sources such as solar power generation and wind power generation, and may be cogeneration equipment, energy storage facilities, mobile power supply vehicles, electric vehicles, or the like. As described above, there is a possibility that the areas L1, L2, and L4 can form an isolating operation section, but other conditions need be confirmed in order to determine whether an isolating operation section can actually be formed. Details of such other conditions for forming an isolating operation section will be described below.

Next, various data included in the database unit DB (see FIG. 1) will be described in detail.

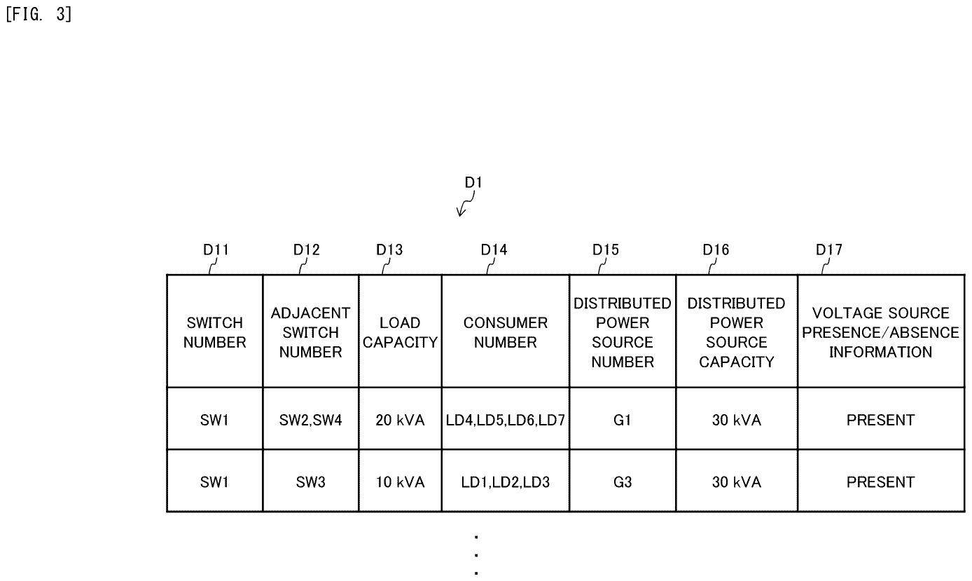

FIG. 3 is a diagram showing an example of a data configuration of the system information D1.

In FIG. 3, the system information D1 includes a record (row) for each area, and each record includes a switch number D11, an adjacent switch number D12, a load capacity D13, a consumer number D14, a distributed power source number D15, a distributed power source capacity D16, and voltage source presence/absence information D17.

The system information D1 shown in FIG. 3 is associated with the power distribution system L (see FIG. 2) managed by the isolating operation planning device 1. The switch number D11 indicates one switch that divides an area related to the records. The adjacent switch number D12 indicates another switch that divides the area. The load capacity D13 indicates a total load capacity of consumers included in the area.

The consumer number D14 indicates an identification number of a consumer included in the area. The distributed power source number D15 indicates an identification number of a distributed power source included in the area. The distributed power source capacity D16 indicates a total power source capacity of the distributed power sources included in the area. The voltage source presence/absence information D17 indicates whether there is a voltage source with a capacity required to operate the area as an isolating operation section.

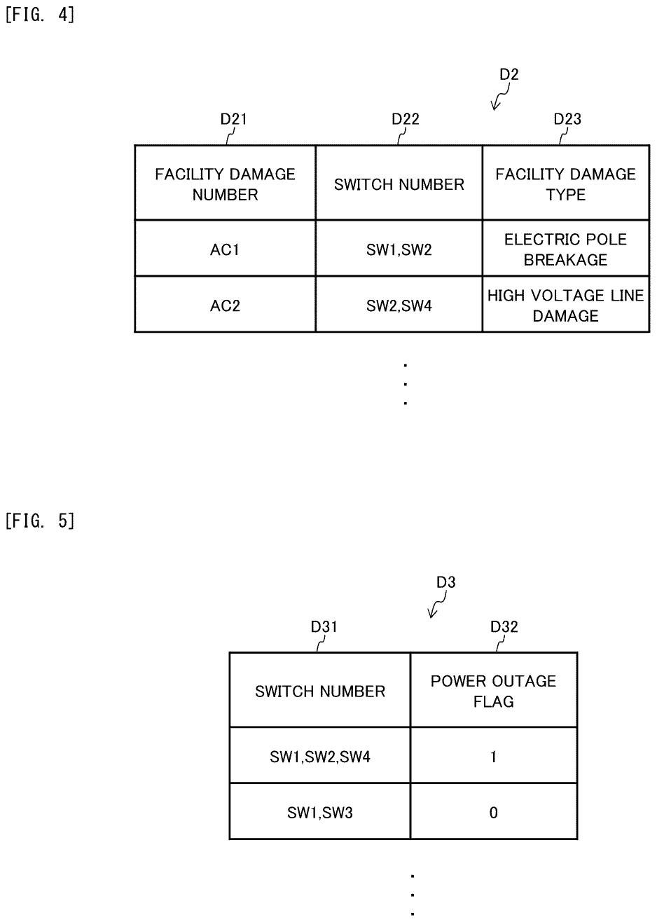

FIG. 4 is a diagram showing an example of a data configuration of the facility damage information D2.

In FIG. 4, the facility damage information D2 includes a record (row) for each damaged location (AC1 and AC2 in the example of FIG. 2), and each record includes a facility damage number D21, a switch number D22, and a facility damage type D23. Information on a serial number that specifies an accident or facility damage in the power distribution system L is stored for the facility damage number D21. In the example shown in the drawing, information specifying the damaged locations AC1 and AC2 (see FIG. 2) is stored.

Here, the damaged location corresponding to the facility damage number D21 is generally sandwiched between a pair of switches. The section sandwiched between this pair of switches is referred to as a switch section. The switch numbers that sandwich the switch section are stored for the switch number D22. For example, the switch numbers of the switches SW1 and SW2 are stored for the damaged location AC1. Further, the switch numbers of the switches SW2 and SW4 are stored for the damaged location AC2.

For the facility damage type D23, information indicating an accident or facility damage corresponding to the facility damage number D21, such as “electric pole breakage” or “high voltage line damage”, is stored. In the example shown in the drawing, it can be seen that “electric pole breakage” has occurred at the damaged location AC1, and “high voltage line damage” has occurred at the damaged location AC2. The facility damage information D2 may further include information indicating the detailed location of the damaged location, such as coordinate information associated with the power distribution system L.

FIG. 5 is a diagram showing an example of a data configuration of the power outage information D3.

In FIG. 5, the power outage information D3 includes a record (row) for each switch section, and each record includes a switch number D31 and a power outage flag D32. Switch numbers that sandwich the switch section in the record are stored for the switch number D31. A power outage flag that is “1” (power outage state) or “0” (power-on state) for the switch section is stored for the power outage flag D32.

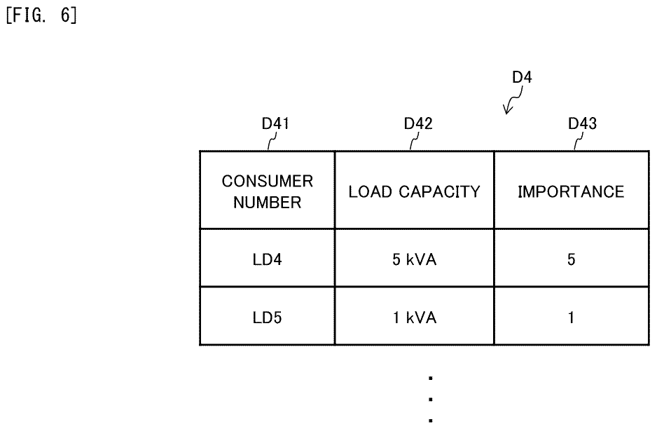

FIG. 6 is a diagram showing an example of a data configuration of the critical load information D4.

In FIG. 6, the critical load information D4 includes a record (row) for each critical load (important consumer), which is a part of the plurality of consumers LD1 to LD14 (see FIG. 2). Here, the “important consumer” is, for example, a hospital or evacuation shelter, but the scope thereof can be determined arbitrarily.

The critical load information D4 includes a consumer number D41, a load capacity D42, and an importance D43 for each record.

The consumer number D41 is a unique identification number that specifies a consumer related to the record, and corresponds to the consumer number D14 in the system information D1 (see FIG. 3). The load capacity D42 is the load capacity of the consumer. The importance D43 indicates the importance of the consumer. The importance D43 is, for example, a number from “1” to “5” in which the larger the number, the more important the consumer is evaluated to be. The importance D43 is not limited thereto as long as it can be handled by the processing in the isolating operation planning unit 7 and a recovery work planning unit 9 to be described below. Although details will be described below, the isolating operation planning unit 7 may not use the importance D43.

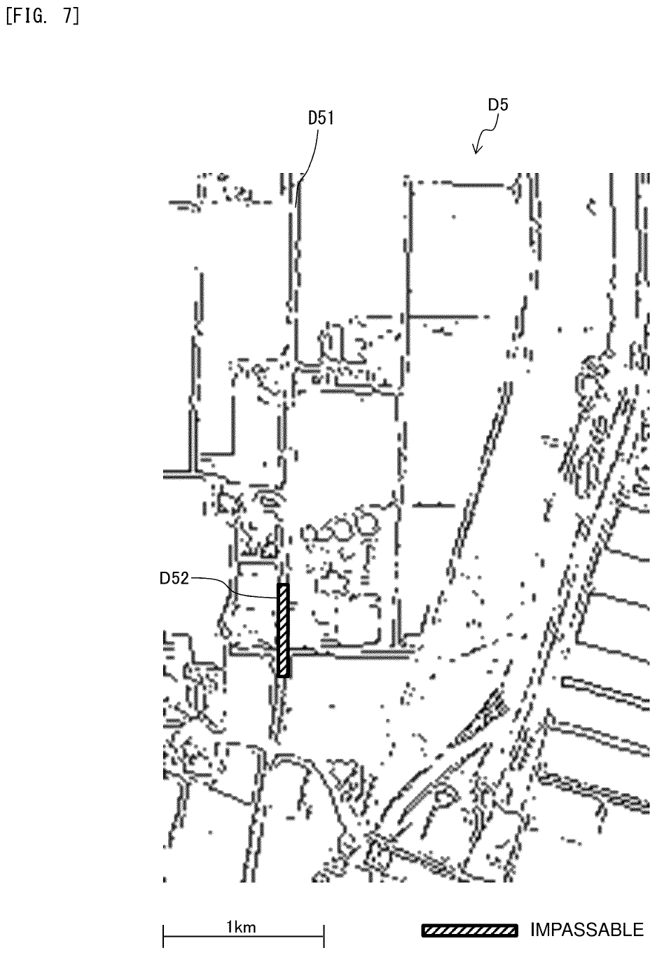

FIG. 7 is a diagram showing an example of a data configuration of the map information D5.

In FIG. 7, the map information D5 includes road information D51 and impassability information D52. The road information D51 is information indicating roads in an area including the power distribution system L (see FIG. 2). The impassability information D52 is information indicating parts of these roads that are impassable. The map information D5 also includes information indicating buildings and the like that belong to the power distribution system L.

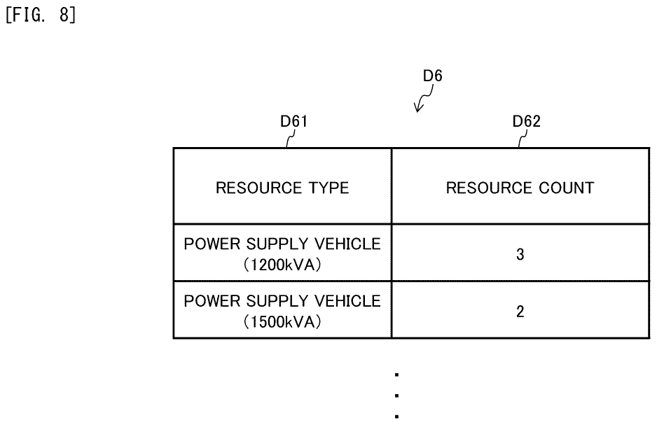

FIG. 8 is a diagram showing an example of a data configuration of the resource information D6.

In FIG. 8, the resource information D6 includes a record (row) for each resource, such as a work vehicle, which can be used in the power distribution system L.

The resource information D6 includes a resource type D61 and a resource count D62 for each record.

The resource type D61 is information indicating the type of vehicle resource. A vehicle is, for example, a high-voltage generator vehicle (hereinafter referred to as a power supply vehicle). In the resource type D61, information on capacities, for example, “power supply vehicle (1200 kVA)” and “power supply vehicle (1500 kVA)” is stored, and power supply vehicles with different capacities may be stored as different resource types.

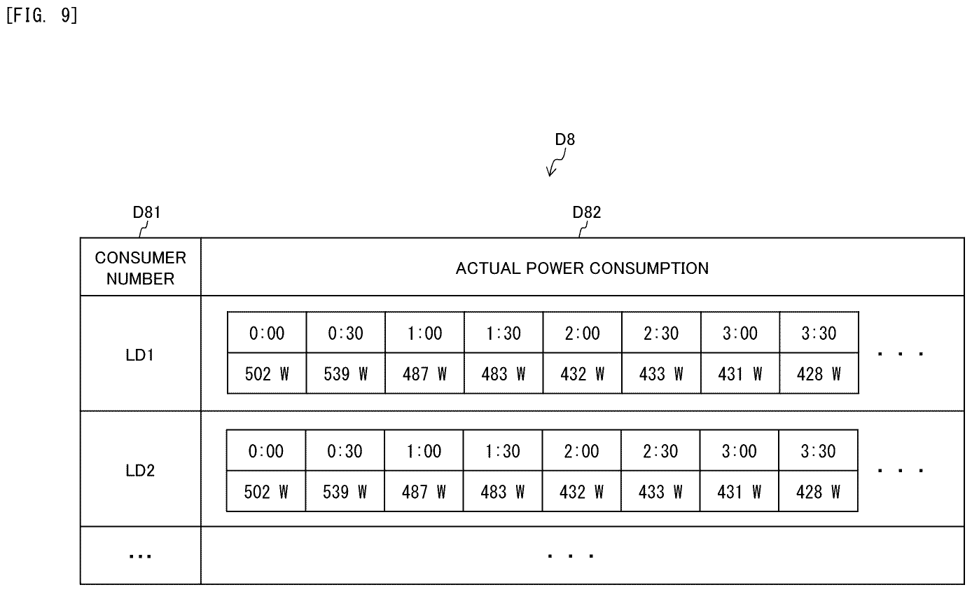

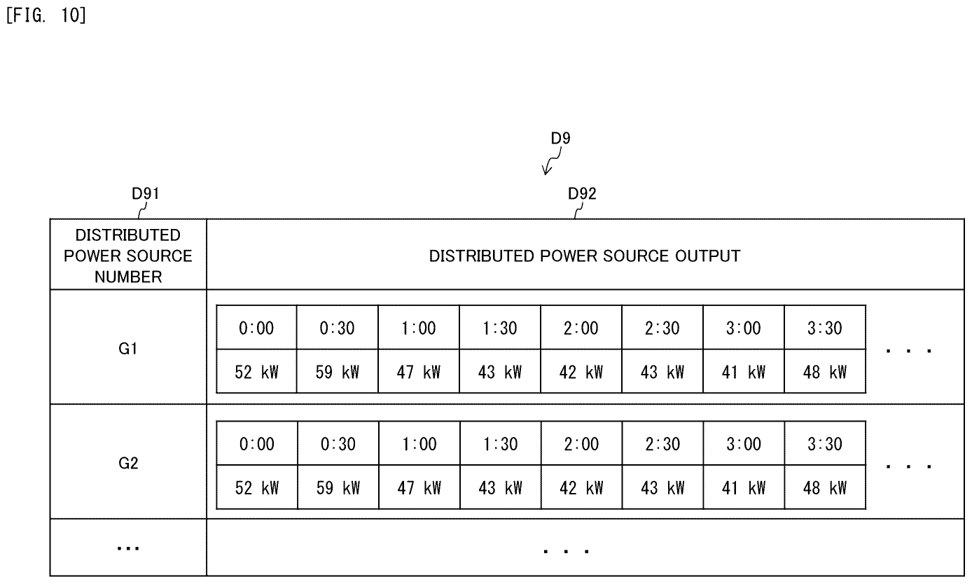

FIG. 9 is a diagram showing an example of a data configuration of the past demand data D8.

In FIG. 9, the past demand data D8 includes a record (row) for each of the consumers LD1 to LD14.

The past demand data D8 includes a consumer number D81 and an actual power consumption D82 for each record.

The consumer number D81 is a unique identification number that identifies a consumer related to the record, and corresponds to the consumer number D14 in the system information D1 (see FIG. 3). The actual power consumption D82 is past time-series data on the power used by the consumer. As the actual power consumption D82, for example, a measurement result obtained by a smart meter owned by a power company may be applied. In addition, the actual power consumption D82 may include outputs of various distributed power sources such as low-voltage solar power generation.

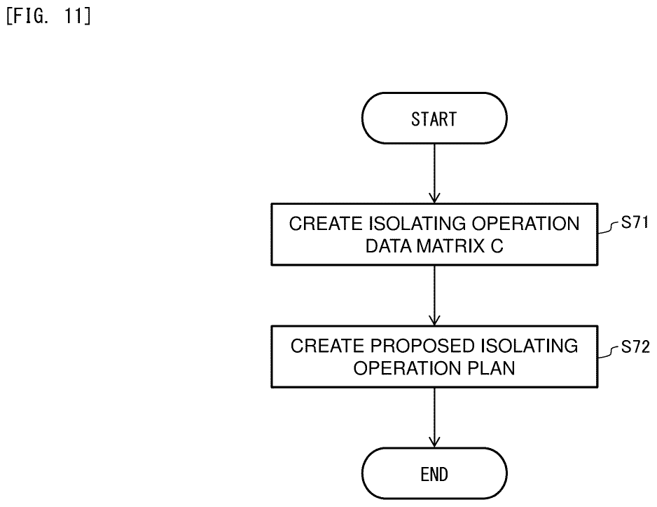

FIG. 10 is a diagram showing an example of a data configuration of the past distributed power source output data D9.

In FIG. 10, the past distributed power source output data D9 includes a record (row) for each of the distributed power sources G1 to G3.

The past distributed power source output data D9 also includes a distributed power source number D91 and an actual distributed power source output result D92 for each record.

The distributed power source number D91 is a unique identification number that identifies a distributed power source related to the record, and corresponds to the distributed power source number D15 in the system information D1 (see FIG. 3). The actual distributed power source output result D92 is past time-series data on the power used by the distributed power source. As the actual distributed power source output result D92, for example, past time-series data on the output of a distributed power source owned by a power company can be applied.

### <Operation of First Embodiment>

Next, the operation of the first embodiment will be described.

First, FIG. 11 is a flowchart of a proposed isolating operation plan creation routine.

This routine is executed by the isolating operation planning unit 7 (see FIG. 1). When the processing proceeds to step S71 (isolating operation planning process) in FIG. 11, the isolating operation planning unit 7 creates an isolating operation data matrix C.

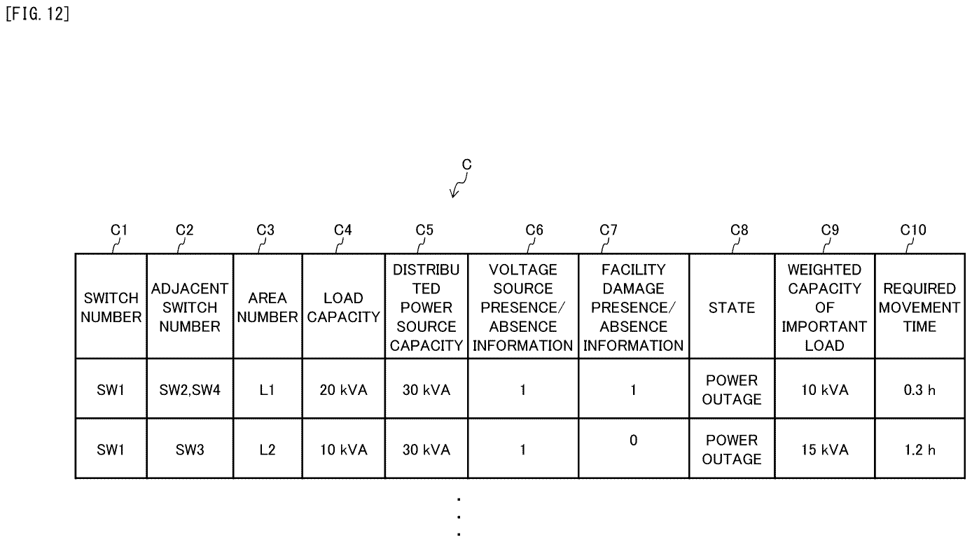

FIG. 12 is a diagram showing an example of the isolating operation data matrix C.

Each of rows of the isolating operation data matrix C corresponds to an area that can be an isolating operation section among areas (for example, L1 to L4 shown in FIG. 2). The “area that can be an isolating operation section” is an area that has the distributed power sources G1 to G3 therein or an area where a power supply vehicle can be disposed.

In step S71 described above, the isolating operation planning unit 7 extracts all of the switch numbers D11 belonging to the power distribution system L managed by the isolating operation planning device 1 from the system information D1 (see FIG. 3), and includes them in the isolating operation data matrix C as switch numbers C1. Furthermore, the isolating operation planning unit 7 reads all of the adjacent switch numbers D12 adjacent to the above-described switch numbers D11 from the system information D1, and includes them in the isolating operation data matrix C as adjacent switch numbers C2.

Furthermore, the isolating operation planning unit 7 assigns area numbers such as “L1” and “L2” (see FIG. 2) to the rows of the isolating operation data matrix C, and includes them in the isolating operation data matrix C as area numbers C3. Through these processes, the switch numbers of the switches required to identify areas, and adjacent areas, that is, areas separated by the same switch, can be unitarily identified by the area numbers.

Furthermore, the isolating operation planning unit 7 reads the load capacity D13, the distributed power source capacity D16, and the voltage source presence/absence information D17 (see FIG. 3) of each area, reads these from the system information D1 as a load capacity C4, a distributed power source capacity C5, and voltage source presence/absence information C6, respectively, and includes them in the isolating operation data matrix C as the load capacity C4.

Furthermore, the isolating operation planning unit 7 specifies an area to which each damaged location belongs based on the switch number D22 of the facility damage information D2 (see FIG. 4). In the example shown in FIG. 4, it is found that both the damaged locations AC1 and AC2 belong to the area L1 (see FIG. 2). Then, the isolating operation planning unit 7 includes facility damage presence/absence information C7, which is binary information that is “1” when there is a damaged location and “0” when there is no damaged location, in the isolating operation data matrix C. However, the facility damage presence/absence information C7 is not limited to the binary information, and may include detailed information on the damaged location. For example, the facility damage presence/absence information C7 may include the contents of the facility damage type D23 (see FIG. 4) of the facility damage information D2 or may include coordinate information of the damaged location.

Furthermore, the isolating operation planning unit 7 reads the power outage flag D32 of each switch section from the power outage information D3 (see FIG. 5). When a power outage flag D32 of any switch section belonging to a certain area is “1” (power outage state), the area is in a “power outage” state. Further, when power outage flags D32 of all switch sections belonging to an area is “0” (power-on state), the area is in a “power-on” state. The isolating operation planning unit 7 includes the “power outage” or “power-on” state in the isolating operation data matrix C as state data C8.

Furthermore, the isolating operation planning unit 7 reads the load capacity D42 and the importance D43 for each critical load from the critical load information D4 (see FIG. 6) and calculates the product of the two (D42×D43). Then, the isolating operation planning unit 7 obtains, for each area, the sum of the products (D42×D43) related to the critical loads belonging to each area, and includes the calculated sum in the isolating operation data matrix C as a weighted capacity C9 of the critical load. Here, the weighted capacity C9 of the critical load is not necessarily required, and a user can arbitrarily determine in advance whether to use the weighted capacity C9 of the critical load. When the weighted capacity C9 of the critical load is not required, it is only required that all of the weighted capacities C9 of the critical loads in the isolating operation data matrix C be set to “0”.

Furthermore, the isolating operation planning unit 7 calculates a required movement time C10 based on the road information D51 and the impassability information D52 of the map information D5, and includes it in the isolating operation data matrix C. Here, a method of calculating the required movement time C10 is described. First, a power supply vehicle, workers, and the like are staying at a known initial position such as an office. The position of a recovery switch that restores the area in the power outage state to a power-on state is also known. The isolating operation planning unit 7 obtains the shortest time required for the power supply vehicle and the workers to move from the initial position to the recovery switch. The obtained shortest time is the required movement time C10.

The required movement time C10 can be calculated by dividing the length of the shortest route from the initial position to the recovery switch by an average movement speed such as 30 km/h. In addition, when the shortest route from the initial position to the recovery switch includes an impassable road section, a route for detouring the section may be applied instead of the shortest route. However, the average movement speed while passing through the impassable road section may be reduced to, for example, 15 km/h to estimate a required time for a detour, and the estimated required time may be set as the required movement time C10. The above-described average movement speed such as 30 km/h and 15 km/h can be set in advance, but is not limited to these speeds.

As described above, according to the example of the isolating operation data matrix C shown in FIG. 12, various states and problems at the time of restoration in each area that may become an isolating operation section are collectively organized and summarized.

Returning back to FIG. 11, next, when the processing proceeds to step S72 (isolating operation planning process), the isolating operation planning unit 7 creates a proposed isolating operation plan DP based on the isolating operation data matrix C. That is, the isolating operation planning unit 7 performs optimization calculation having an objective function and constraint conditions to be described below to create the proposed isolating operation plan DP. Thereby, it is possible to determine areas that can maximize a load capacity that can be restored from a power outage when isolating operation can be performed, that is, to minimize power outage damage. In addition, it is possible to create the proposed isolating operation plan DP that includes a power restoration timing of each area in a process up to the final system configuration of the isolating operation.

### (Objective Function)

First, a binary variable BV (not shown) that is “0” when an assumed state of each area is a power outage state and “1” when an assumed state is an isolating operation state. Further, for each area, a virtual load capacity LC (not shown), which is the sum of the load capacity C4 shown in FIG. 12 and the weighted capacity C9 of the critical load, is assumed. In addition, the sum of the virtual load capacities LC in all areas is defined as a total virtual load capacity LCA (not shown).

An objective function for performing the optimization calculation is a total virtual load capacity LCA for each time step. That is, the objective of this embodiment is to maximize the total virtual load capacity LCA for each time step. Here, the time step can be arbitrarily set to, for example, 5 minutes by the user. Thereby, it is possible to create a proposed isolating operation plan DP including a power restoration timing for each switch section so that as many loads as possible are restored from a power outage as rapidly as possible. Thereby, when an critical load is taken into consideration, it is possible to create an isolating operation plan for restoring power preferentially in accordance with the importance.

### (Constraint Conditions)

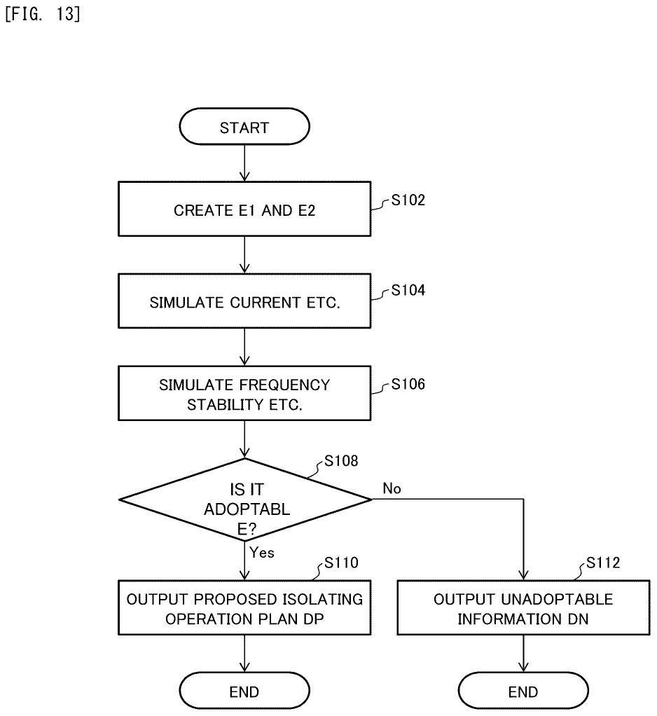

In addition, main constraint conditions for performing the optimization calculation are constraint conditions CA, CB, and CC shown below.
The constraint condition CA is that “the facility damage presence/absence information C7 (see FIG. 12) is “0””, that is, “no accident or facility failure occurs in the area”. This is because, when isolating operation is performed in the area regardless of the occurrence of an accident or facility failure, there is a possibility that a re-power outage or electric shock damage will occur.
The constraint condition CB is that “isolating operation is not performed in an area for which the voltage source presence/absence information C6 (see FIG. 12) is “0” (no voltage source) unless the area is associated with other areas”. Here, when isolating operation is performed in each of adjacent areas, it is assumed that operation is necessarily performed in the areas in association with each other. Adjacent areas may be identified based on the adjacent switch numbers C2 (see FIG. 12). Thereby, when an area scheduled for isolating operation does not have a voltage source, isolating operation can be performed in association with other areas.
The constraint condition CC is a condition added by the constraint addition unit 11 (see FIG. 1). Details of the constraint condition CC will be described below, but the constraint condition CC is not particularly set at a stage when a system analysis routine (FIG. 13) to be described below is executed for the first time.

FIG. 13 is a flowchart of the system analysis routine executed by the system analysis unit 10, and system analysis is performed by steps SS102 to S112 (system analysis process) in this routine.

When the processing proceeds to step S102 in FIG. 13, the system analysis unit 10 creates a demand prediction E1 and a distributed power source output prediction E2 for the proposed isolating operation plan DP previously created by the isolating operation planning unit 7. Here, the demand prediction E1 is a prediction of power demand after the start of power supply in each area where isolating operation is performed. Further, the distributed power source output prediction E2 is a prediction of the output of the distributed power source after the start of power supply in each area where isolating operation is performed. The system analysis unit 10 creates the demand prediction E1 and the distributed power source output prediction E2 based on the past demand data D8 (see FIG. 9), the past distributed power source output data D9 (see FIG. 10), and the like by, for example, regression analysis or the like.

Next, when the processing proceeds to step S104, the system analysis unit 10 simulates a current and the like in the power distribution system L. For this reason, the system analysis unit 10 creates a power distribution system model LM (not shown) that simulates the power distribution system L (see FIG. 2). The power distribution system model LM includes a voltage source model, a load model, a transformer model, a contracted load model, and the like that simulate a voltage source, a load, a transformer, and the like. The system analysis unit 10 sets time-series parameters of these various models at a current analysis time interval (for example, one millisecond) that is arbitrarily set by the user in advance, and simulates the movement, particularly a current and the like in the power distribution system model LM. Thereby, the system analysis unit 10 calculates an inrush current at each time.

Incidentally, the user arbitrarily determines in advance a trip determination criterion for tripping each distributed power source in a simulated manner. This determination criterion includes a current value trip determination criterion related to a current value and a frequency trip determination criterion related to a frequency. The current value trip determination criterion is, for example, a criterion such as “when a current exceeding a rated output of the distributed power source for one second or more occurs, the distributed power source is tripped in a simulated manner”. Then, in the power distribution system model LM, the distributed power source is tripped in a simulated manner at a timing when the current value trip determination criterion is satisfied. The transformer and load in the power distribution system L may be modeled, for example, by their respective equivalent circuits.

Next, when the processing proceeds to step S106, the system analysis unit 10 simulates frequency stability and the like in the power distribution system L. That is, based on the demand prediction E1, the distributed power source output prediction E2, and the simulation result of step S104, supply and demand frequency stability and the like are simulated at a frequency analysis time interval (for example, one second) which is set by the user in advance. As described above, the trip determination criterion that can be arbitrarily determined by the user also includes a frequency trip determination criterion. This frequency trip determination criterion is, for example, a criterion such as “an event in which the frequency is lower than a reference frequency by 2.5 Hz or more has occurred”. Thus, in the power distribution system model LM, a distributed power source is tripped at the time when this criterion is satisfied. Thereby, it is possible to simulate a change in frequency deviation over time and the tripping of the distributed power source due to frequency deviation.

In the above-described steps S104 and S106, the simulation has been performed to analyze the inrush current, frequency, and the like, but physical quantities analyzed here are not limited thereto. For example, voltage analysis by tidal current calculation, energy residual quantity simulation of energy storage facilities, and the like may be added to steps S104 and S106.

Next, when the processing proceeds to step S108, the system analysis unit 10 determines whether the proposed isolating operation plan DP previously created by the isolating operation planning unit 7 is adoptable based on the simulation results of steps S104 and S106 and the like.

A determination criteria for determining whether the proposed isolating operation plan DP is adoptable can be arbitrarily set by the user. For example, when tripping of a distributed power source occurs even once in the simulations of steps S104 and S106 and the like, it is considered that the proposed isolating operation plan DP is “not adoptable”. In this manner, it may be determined whether the proposed isolating operation plan DP is adoptable depending on whether there is a possibility that re-power outage will occur when the proposed isolating operation plan DP created by the isolating operation planning unit 7 is executed.

When the determination result of step S108 is “Yes” (adoptable), the processing proceeds to step S110. Here, the system analysis unit 10 outputs the proposed isolating operation plan DP via the screen output unit 12, the display device 13 (see FIG. 1), and the like. On the other hand, when the determination result of step S108 is “No” (not adoptable), the processing proceeds to step S112. Here, the system analysis unit 10 outputs unadoptable information DN to the constraint addition unit 11 (see FIG. 1). This unadoptable information DN may include an event which is the cause of the determination that isolating operation cannot be performed, and the time in the simulation when the event occurred.

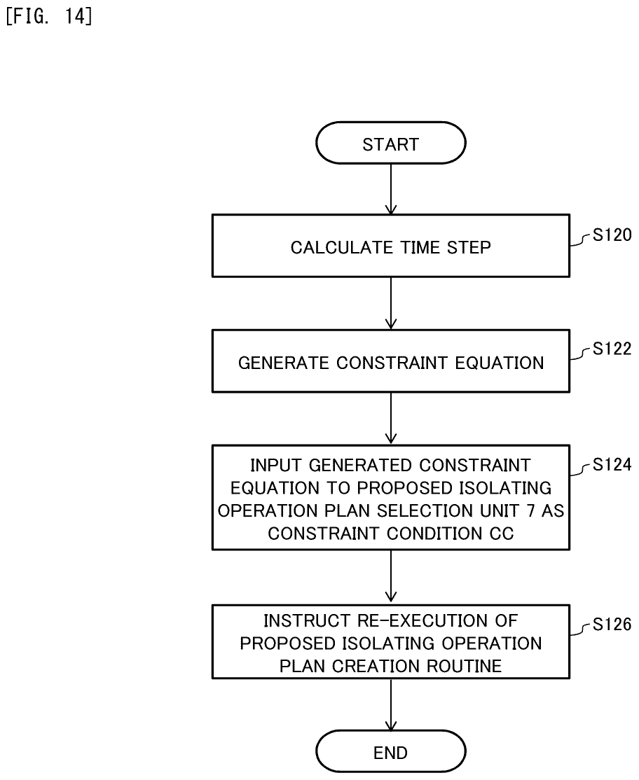

FIG. 14 is a flowchart of a constraint addition routine executed by the constraint addition unit 11, and in this routine, the above-described constraint condition CC is added to the isolating operation planning unit 7 through steps S120 to S126 (constraint addition process).

When the processing proceeds to step S120 in FIG. 14, the constraint addition unit 11 calculates a real-time time step in which an event making isolating operation impossible occurred for the power distribution system model LM for which it is determined that “isolating operation cannot be performed”. That is, the time in the simulation at which the event making isolating operation impossible occurred is converted into a time step. Thereby, it can be determined in which time step in the proposed isolating operation plan there is a possibility that an event being the cause of occurrence of a re-power outage will occur.

Next, when the processing proceeds to step S122, a constraint equation to be input to the isolating operation planning unit 7 is generated for a time step in which an event being the cause of occurrence of a re-power outage may occur. This constraint equation is preferably related to a physical quantity that is correlated with the event being the cause of occurrence of a re-power outage among the input information or variables handled by the isolating operation planning unit 7 described above.

As an example, a case where an event being the case of occurrence of a re-power outage is tripping of a distributed power source due to frequency deviation is considered. In this case, it is considered that a load capacity of a certain consumer in an area correlated with a frequency is constrained to less than a predetermined value in the time step. At this time, various methods are conceivable for the extent to which the load capacity is constrained, and thus a method of constraining the load capacity is not limited. In addition, a physical quantity other than the load capacity in the area that is correlated with frequency deviation or other phenomena may be selected, and can be arbitrarily set by the user in advance.

Next, when the processing proceeds to step S124 in FIG. 14, the constraint addition unit 11 outputs the constraint equation generated in step S122 described above to the isolating operation planning unit 7 as a constraint condition CC. Thereby, the isolating operation planning unit 7 sets the constraint condition CC for the isolating operation planning unit 7. Next, when the processing proceeds to step S126, the constraint addition unit 11 instructs the isolating operation planning unit 7 to execute the proposed isolating operation plan creation routine (FIG. 11) again to which the constraint condition CC is added. With the above description, the processing of this routine ends.

Thereby, the isolating operation planning unit 7 executes the proposed isolating operation plan creation routine (FIG. 11) again based on a newly added constraint condition CC to create a proposed isolating operation plan again. Then, the system analysis unit 10 executes the system analysis routine (FIG. 13) again to determine again whether the new proposed isolating operation plan can be adopted. As described above, since the new proposed isolating operation plan is created after the above-described constraint condition CC is added, there is a high possibility that the determination result of step S108 in FIG. 13 will be “Yes” (adoptable).

However, for the new proposed isolating operation plan, the determination result of step S108 may also be “No” (unadoptable). In this case, the constraint addition routine (FIG. 14) is executed again, and the constraint addition unit 11 updates the contents of the constraint condition CC. As described above, until “adoptable” is written for the created proposed isolating operation plan, the execution of the proposed isolating operation plan creation routine (FIG. 11) by the isolating operation planning unit 7, the execution of the system analysis routine (FIG. 13) by the system analysis unit 10, and the execution of the constraint addition routine (FIG. 14) by the constraint addition unit 11 are cyclically repeated.

Thereby, in the process of actually configuring an isolating operation system in each area, it is possible to formulate an isolating operation plan capable of restoring as many loads as possible as rapidly as possible while avoiding a re-power outage in each time step. Here, the above-described isolating operation plan includes a combination of a plurality of areas and power restoration timing information. In addition, the power restoration timing information includes either the power restoration time (power restoration timing) of each area or the order of power restoration.

Further, in the series of processes, the isolating operation planning unit 7 can select a solution of “not executing isolating operation for all areas” to prevent the process from never ending. For example, when the determination result is not “adoptable” even when the isolating operation planning unit 7 creates a proposed isolating operation plan a predetermined number of times, it is conceivable to prevent isolating operation from being executed for all areas.

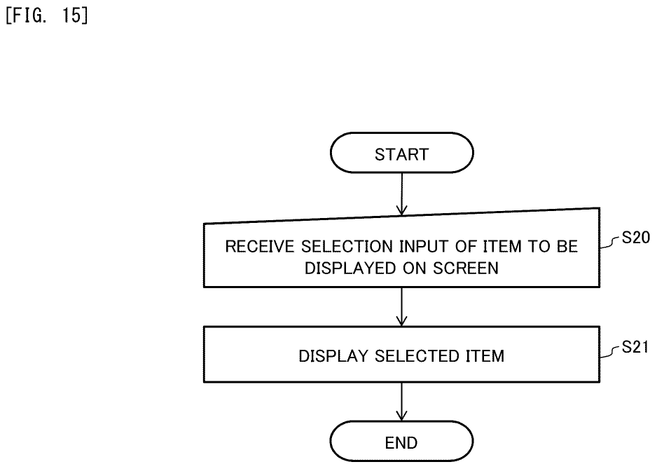

FIG. 15 is a flowchart of a display processing routine executed by the screen output unit 12.

When the processing proceeds to step S20 in FIG. 15, the screen output unit 12 receives a selection input of an item to be displayed on the display device 13 from the user. Next, when the processing proceeds to step S21, the screen output unit 12 displays contents related to the selected item on the display device 13. In this manner, the screen output unit 12 has a function of selecting and displaying the contents to be displayed on the display device 13.

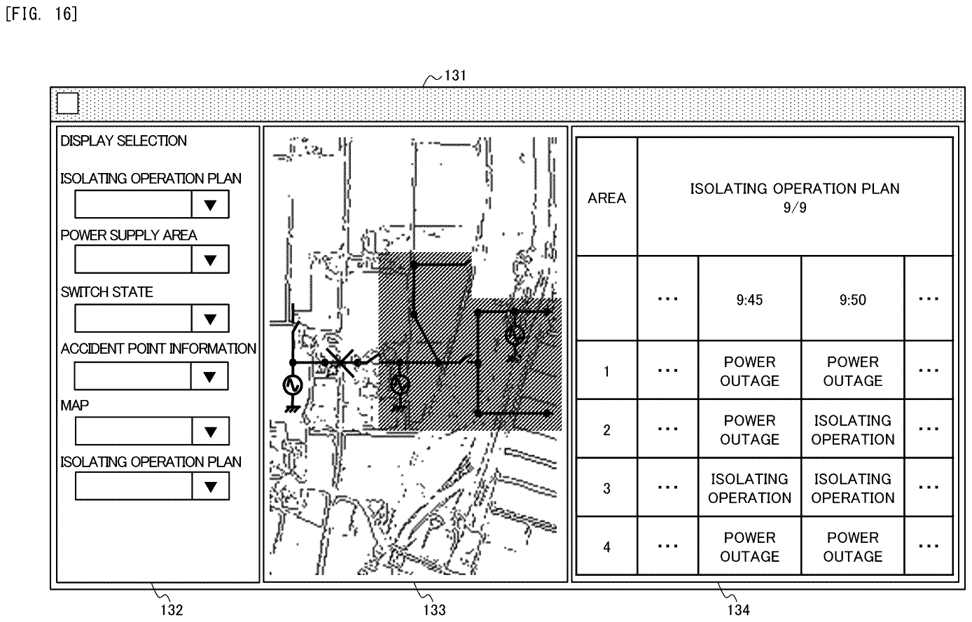

FIG. 16 is a diagram showing a configuration example of a screen 131 displayed on the display device 13 by the screen output unit 12.

In FIG. 16, the screen 131 includes panes 132, 133, and 134 that are connected in sequence in the horizontal direction.

As described above, the screen output unit 12 displays the contents selected by the user on the display device 13 as the screen 131. The display content selection pane 132 is provided such that an operator can operate and select the display content to be selected and processed by the screen output unit 12. Thereby, the display content selected by the display content selection pane 132 is displayed in the other panes.

The screen output unit 12 may display, for example, buttons or pull-downs in the display content selection pane 132. When the operator presses or selects one or a plurality of buttons or pull-downs displayed on the display device 13, the screen output unit 12 outputs the display content selected by the operator to another pane displayed on the display device 13. In the example of FIG. 16, items that can be selected in the display content selection pane 132 are, for example, a power supply area, a switch state, accident point information, a map of roads, houses, and the like, an isolating operation sequence, and the like according to the proposed isolating operation plan created by the isolating operation planning unit 7. When the user selects any of these items, the screen output unit 12 receives a selection input of an item to be displayed on the screen in step S21 of the display processing routine (FIG. 15). Thereafter, in step S22 of the same routine, the screen output unit 12 displays a display screen according to the selected contents in the map pane 133 and the plan information pane 134.

In the map pane 133, an isolating operation plan and a map of roads, houses, and the like corresponding to a positional relationship are displayed to be superimposed on each other. The isolating operation plan is a system diagram in which each system is colored to be identifiable. For example, in the system diagram, switches in an open state and a closed state are displayed in different colors to indicate the states of the switches in the system, and for example, the location of an accident point is displayed with a symbol such as a cross. For example, areas where power can be supplied by isolating operation are displayed in different colors on the map.

Specific contents of the item selected in the display content selection pane 132 are displayed in the plan information pane 134. FIG. 16 shows an example in which information when an isolating operation sequence is selected is displayed in detail. The isolating operation sequence is a screen that shows whether each area is in an isolating operation state, a power-on state, or a power outage state at each time.

It is also considered that the isolating operation planning device 1 of this embodiment is used for purposes other than isolating operation planning. For example, this embodiment is used at normal times when no disaster occurs, and candidate locations for installing distributed power sources such as storage batteries and solar power generation facilities are given as inputs. By planning an area where power will be restored in a simulated manner, it is possible to confirm the effect of reducing the damage caused by power outages when distributed power sources are installed in candidate locations, which contributes to decision-making regarding the installation of the distributed power sources. For example, when attempting to identify an accident section using a time-limited sequential method with a distributed power source as a power source, it is also possible to plan the time, timing, and order of power restoration by using this embodiment. In these applications, even when a situation on a demand side changes due to power consumption control by smart meters, demand response, or the like, the information can be reflected in input data to create a plan.

When a business is developed using this embodiment, several aspects are conceivable. For example, an aspect may be adopted in which a business entity other than a power distribution operator may own the isolating operation planning device 1 according to this embodiment, and when a power distribution company needs the service according to this embodiment, the power distribution company provides necessary input information to the above-described business entity, and the above-described business entity provides a proposed plan as a service. For example, in order for the power distribution operator to own the isolating operation planning device 1, the above-described business entity may trade the service of formulating an isolating operation plan. For example, the existing device, system, or the like owned by the power distribution operator may be equipped with the isolating operation planning device 1 according to this embodiment as a function, and the above-described business entity may trade the service of formulating an isolating operation plan.

### [Effects of Embodiment]

According to the embodiment described above, the isolating operation planning device 1 includes the isolating operation planning unit 7, the system analysis unit 10, and the constraint addition unit 11. The isolating operation planning unit 7 creates, in order to perform isolating operation for the power system section (L) isolated from the power system GL, the proposed isolating operation plan DP with the areas L1 to L4 as isolating operation sections, the areas L1 to L4 having at least the distributed power sources G1 to G3 therein or being equipped with power supply vehicles, among the areas L1 to L4 that are included in the isolating power system section (L) and are divided by the adjacent switches SW1 to SW4. The system analysis unit 10 performs system analysis based on the proposed isolating operation plan DP and determines whether isolating operation can be performed. When the system analysis unit 10 determines that isolating operation cannot be performed, the constraint addition unit 11 adds the constraint condition CC at the time of creating the proposed isolating operation plan DP to cause the isolating operation planning unit 7 to create the proposed isolating operation plan DP again.

Thereby, the system analysis unit 10 performs system analysis based on the proposed isolating operation plan DP, and the constraint addition unit 11 can add the constraint condition CC based on a system analysis result, whereby it is possible to formulate an appropriate isolating operation plan with a high possibility of realizing isolating operation.

Furthermore, when the system analysis unit 10 determines that isolating operation cannot be performed, the system analysis unit 10 outputs unadoptable information DN including the timing when an event making isolating operation impossible occurs, and it is more preferable that the isolating operation planning unit 7 include, in the proposed isolating operation plan DP, the final open/closed states of the switches SW1 to SW4 and either time-series information for changing the open/closed states of the switches SW1 to SW4 or the order in which the open/closed states of the switches SW1 to SW4 are changed. Thereby, it is possible to specify the open/closed states of the switches SW1 to SW4 in accordance with the timing when an event making isolating operation impossible occurs, and to formulate a more appropriate proposed isolating operation plan DP.

Furthermore, it is more preferable that the proposed isolating operation plan DP be for planning a configuration of an isolating operation system in each of a plurality of time steps. Thereby, it is possible to formulate a more appropriate proposed isolating operation plan DP corresponding to each of the time steps.

Further, it is more preferable that the constraint addition unit 11 outputs, to the isolating operation planning unit 7, a constraint condition CC for resolving an event at a timing when an event making isolating operation impossible occurs. Thereby, it is possible to further increase the possibility that the isolating operation planning unit 7 can output a proposed isolating operation plan DP that makes isolating operation possible.

In addition, it is more preferable that the isolating operation planning device 1 further includes the screen output unit 12 that displays, on the display device 13, any one of the timing when an event making isolating operation impossible occurs, the final open/closed states of the switches SW1 to SW4, the time-series information for changing the open/closed states of the switches SW1 to SW4, or the order in which the open/closed states of the switches SW1 to SW4 are changed. Thereby, the user can visually grasp the contents of the proposed isolating operation plan DP.

Further, it is more preferable that the isolating operation planning unit 7 can create a proposed isolating operation plan DP in which isolating operation is not performed for all of the areas L1 to L4. Thereby, when it is difficult to perform isolating operation, the user can recognize the difficulty in performing isolating operation.

### Modification Example

The invention is not limited to the above-described embodiment, and various modifications can be made. The above-described embodiment is exemplified to describe the invention in an easy-to-understand manner, and is not necessarily limited to having all of the configurations described. In addition, it is possible to replace a part of a configuration of a certain embodiment with a configuration of another embodiment, and it is also possible to add a configuration of a certain embodiment to a configuration of another embodiment. In addition, it is possible to delete a part of a configuration of each embodiment or add or replace other configurations. In addition, the control lines and information lines shown in the drawing are those that are considered to be necessary for description, and do not necessarily show all control lines and information lines necessary on a product. In reality, it may be considered that almost all configurations are connected to each other. Possible modifications of the above-described embodiment are, for example, as follows.

(1) Since the hardware of the isolating operation planning device 1 in the above-described embodiment can be realized by a general computer, the flowcharts shown in FIG. 11 and FIGS. 13 to 15, other programs for executing the above-described various processes, and the like may be stored in a storage medium (a computer-readable recording medium on which a program is recorded) or distributed via a transmission path.

(2) In the above-described embodiment, the processes shown in FIG. 11 and FIGS. 13 to 15 and other processes described above are described as software processes using a program, but some or all of them may be replaced with hardware processes using an application specific integrated circuit (ASIC), a field programmable gate array (FPGA), or the like.

(3) The various processes executed in the above-described embodiment may be executed by a server computer via a network (not shown), and various data stored in the above-described embodiment may also be stored in the server computer.

### REFERENCE SIGNS LIST

1: isolating operation planning device (computer)
7: isolating operation planning unit (isolating operation planning means)
10: system analysis unit (system analysis means)
11: constraint addition unit (constraint addition means)
12: screen output unit (screen output process)
13: display device
L: power distribution system (power system section)
CC: constraint condition
DN: unadoptable information
DP: proposed isolating operation plan
GL: power system
G1 to G3: distributed power source
L1 to L4: area
S71, S72: step (isolating operation planning process)
SW1 to SW4: switch
S102 to S112: (system analysis process)
S120 to S126: (constraint addition process)

1. An isolating operation planning device comprising:
an isolating operation planning unit that, in order to perform isolating operation for a power system section isolated from a power system, creates a proposed isolating operation plan with areas as isolating operation sections, the areas having at least distributed power sources therein or being equipped with power supply vehicles, among areas that are included in the isolating power system section and are divided by adjacent switches;
a system analysis unit that performs system analysis based on the proposed isolating operation plan and determines whether isolating operation is able to be performed; and
a constraint addition unit that, when the system analysis unit determines that isolating operation is not able to be performed, adds a constraint condition when creating the proposed isolating operation plan to cause the isolating operation planning unit to create the proposed isolating operation plan again.

2. The isolating operation planning device according to claim 1, wherein,
when the system analysis unit determines that isolating operation is not able to be performed, the system analysis unit outputs unadoptable information including a timing when an event making isolating operation impossible occurs, and
the isolating operation planning unit includes, in the proposed isolating operation plan, final open/closed states of the switches and either time-series information for changing the open/closed states of the switches or an order in which the open/closed states of the switches are changed.

3. The isolating operation planning device according to claim 2, wherein the proposed isolating operation plan is for planning a configuration of an isolating operation system in each of a plurality of time steps.

4. The isolating operation planning device according to claim 2, wherein the constraint addition unit outputs, to the isolating operation planning unit, the constraint condition for resolving the event at the timing when the event making isolating operation impossible occurs.

5. The isolating operation planning device according to claim 2, further comprising a screen output unit that displays, on a display device, any of the timing when the event making isolating operation impossible occurs, the final open/closed states of the switches, the time-series information for changing the open/closed states of the switches, or the order in which the open/closed states of the switches are changed.

6. The isolating operation planning device according to claim 1, wherein the isolating operation planning unit is able to create the proposed isolating operation plan in which isolating operation is not performed for all of the areas.

7. An isolating operation planning method causing a computer to execute:
an isolating operation planning process of, in order to perform isolating operation for a power system section isolated from a power system, creating a proposed isolating operation plan with areas as isolating operation sections, the areas having at least distributed power sources therein or being equipped with power supply vehicles, among areas that are included in the isolating power system section and are divided by adjacent switches;
a system analysis process of performing system analysis based on the proposed isolating operation plan and determining whether isolating operation is able to be performed; and
a constraint addition process of, when it is determined that isolating operation is not able to be performed in the system analysis process, adding a constraint condition when creating the proposed isolating operation plan to execute the isolating operation planning process again.

8. The isolating operation planning method according to claim 7, wherein
the system analysis process is a process of outputting unadoptable information including a timing when an event making isolating operation impossible occurs when it is determined that isolating operation is not able to be performed, and
the isolating operation planning process is a process of including, in the proposed isolating operation plan, final open/closed states of the switches and either time-series information for changing the open/closed states of the switches or an order in which the open/closed states of the switches are changed.

9. The isolating operation planning method according to claim 8, wherein the proposed isolating operation plan is for planning a configuration of an isolating operation system in each of a plurality of time steps.

10. The isolating operation planning method according to claim 8, wherein the constraint addition process outputs the constraint condition for resolving the event at the timing when the event making isolating operation impossible occurs in the isolating operation planning process.

11. The isolating operation planning method according to claim 8, further causing the computer to execute a display output process of displaying, on a display device, any of the timing when the event making isolating operation impossible occurs, the final open/closed states of the switches, the time-series information for changing the open/closed states of the switches, or the order in which the open/closed states of the switches are changed.

12. The isolating operation planning method according to claim 7, wherein, in the isolating operation planning process, the proposed isolating operation plan in which isolating operation is not performed for all of the areas is able to be created.

13. A program causing a computer to function as:
an isolating operation planning means that, in order to perform isolating operation for a power system section isolated from a power system, creates a proposed isolating operation plan with areas as isolating operation sections, the areas having at least distributed power sources therein or being equipped with power supply vehicles, among areas that are included in the isolating power system section and are divided by adjacent switches;
a system analysis means that performs system analysis based on the proposed isolating operation plan and determines whether isolating operation is able to be performed; and
a constraint addition means that, when the system analysis means determines that isolating operation is not able to be performed, adds a constraint condition when creating the proposed isolating operation plan to cause the isolating operation planning means to create the proposed isolating operation plan again.
